(19) United States
(12) Patent Application Publication
(10) Pub. No.: US 2008/0061430 A1
(43) Pub. Date: Mar. 13, 2008

(54) Structure of heat dissipated submount

(75) Inventors: Jyh-Chen Chen, Jhongli City (TW); Jenq-Yang Chang, Jhongli City (TW); Farn-Shiun Hwu, Jhongli City (TW); Yeeu-Chang Lee, Jhunan Township (TW); Gwo-Jiun Sheu, Tainan City (TW); Sheng-Han Tu, Tainan City (TW); Long-Sing Ye, Jhonghe City (TW)

Correspondence Address: TROXELL LAW OFFICE PLLC, SUITE 1404, 5205 LEESBURG PIKE, FALLS CHURCH, VA, 22041, US

(73) Assignee: National Central University, Jhongli City (TW)

(21) Appl. No.: 11/526,070

(22) Filed: Sep. 25, 2006

(30) Foreign Application Priority Data
Sep. 7, 2006 (TW) 095133117

(51) Int. Cl. H01L 23/34

(52) U.S. Cl. 257/712; 257/E23.08

(57) ABSTRACT

A structure of a submount for thermal package has a high heat dissipation and a low spreading thermal resistance. The submount has a specific ratio of height to side length.

### FIELD OF THE INVENTION

The present invention relates to a heat dissipating; more particularly, relates to effectively diminishing a spreading thermal resistance of a submount with a specific size ratio.

### DESCRIPTION OF THE RELATED ARTS

A prior art in Taiwan is called “A thin heat spreader for integrated circuit (IC) package”, comprising a closed metal case being thin and having a flat exposed surface for heat exchange; a plurality of capillary structures in the metal case; and a fluid filled in the metal case for heat exchange, characterized in that the metal case is made of a metal having a low coefficient of thermal expansion.

Another prior art is a U.S. Pat. No. 5,696,665, “Integrated circuit package with diamond heat sink.” The prior art is an IC package comprising: an integrated circuit; a lead frame having a plurality of legs in electrical connection with the integrated circuit; and an electrically insulating, thermally conductive substrate having first and second faces, where the first face is coated with diamond film which is in intimate thermal contact with both the integrated circuit and the plurality of legs of the lead frame; and the bulk of the substrate comprises a thermally-conductive non-diamond material.

Because electrical components having high capacity and light-emitting diodes having high power is becoming minimized, the power input and the heat density increases tremendously and these situations are not easily dealt with by using the prior arts. Hence, the prior arts do not fulfill users' requests on actual use.

### SUMMARY OF THE INVENTION

The main purpose of the present invention is to effectively diminish a spreading thermal resistance of a submount and to obtain a characteristic of high heat density dissipating.

To achieve the above purpose, the present invention is a structure of a heat dissipated submount, comprising a sub mount of high thermal conductivity and a cooling device, where the submount has at least one heat source at a side; the submount has a square bottom or a circular bottom; the submount has a side length smaller than 5 centimeter; and the submount has a ratio of height to side length or diameter between 0.05 and 0.45. Accordingly, a novel structure of a heat dissipated submount is obtained.

### BRIEF DESCRIPTIONS OF THE DRAWINGS

The present invention will be better understood from the following detailed description of the preferred embodiment according to the present invention, taken in con junction with the accompanying drawings, in which

FIG. 1 is the perspective view showing the preferred embodiment according to the present invention;

FIG. 2 is the view showing the specific curves of thermal resistances;

FIG. 3 is the view showing the curves of one-dimensional material thermal resistances.

### DESCRIPTION OF THE PREFERRED EMBODIMENT

The following description of the preferred embodiment is provided to understand the features and the structures of the present invention.

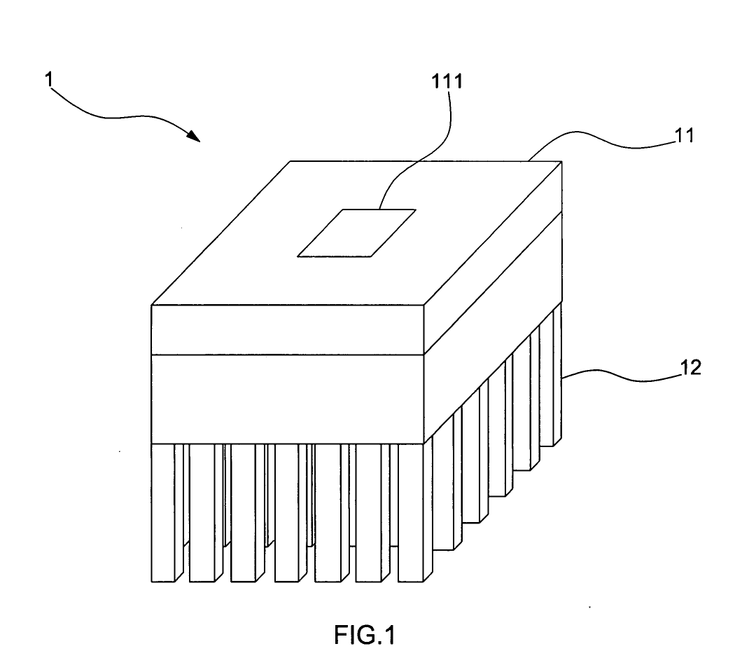

Please refer to FIG. 1, which is a perspective view showing a preferred embodiment according to the present invention. As shown in the figure, the present invention is a structure of a heat dissipated submount 1, comprising a submount 11 and a cooling device 12, where the submount 11 has at least one heat source 111 at a side; and the cooling device 12 is cove red at another side of the sub mount 11 not adjacent to the heat source 111.

The submount 11 is a heat pipe, a heat spreader or a micro heat pipe made of a material of high thermal conductivity, such as silicon carbide, aluminum nitride, aluminum, copper or diamond. The material has a thermal conductivity between 1 watt per meter per kelvin (W/mK) and 2000 W/mK. The submount 11 has a square bottom or a circular bottom; the side length or diameter of the submount 11 is smaller than 5 centimeter; and the submount 11 has a ratio of height to the side length or the diameter between 0.05 and 0.45.

The heat source 111 at the side of the submount 11 is an electric chip or a light-emitting diode; the heat source 111 is square or circular; and there are a plurality of heat sources 111 in an array arrangement.

The cooling device 12 is a plurality of heat dissipated fins, a water cooler or a thermoelectric cooler. Thus, a novel structure of a heat dissipated submount is obtained.

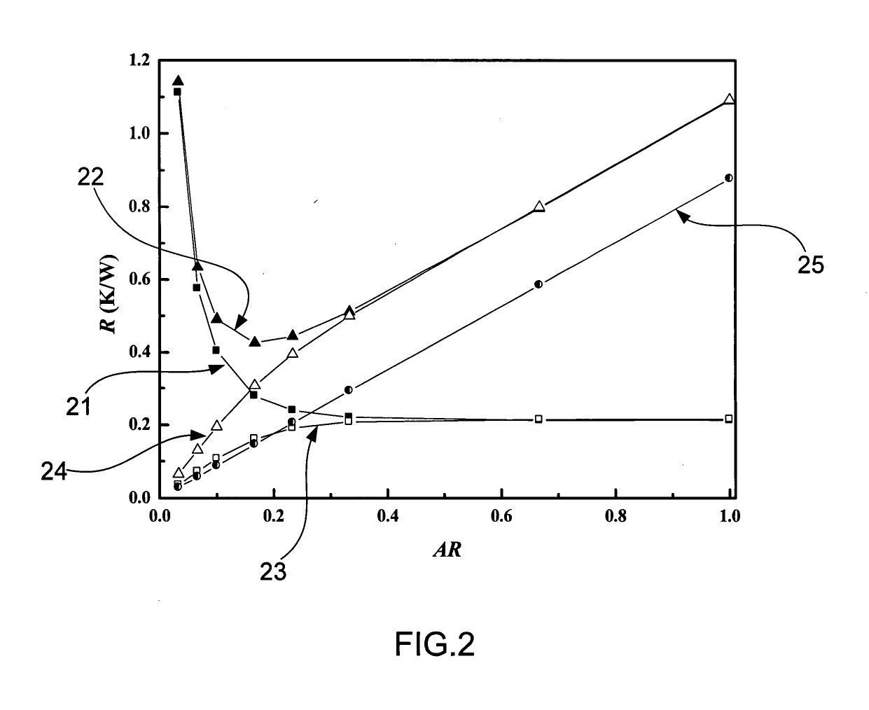

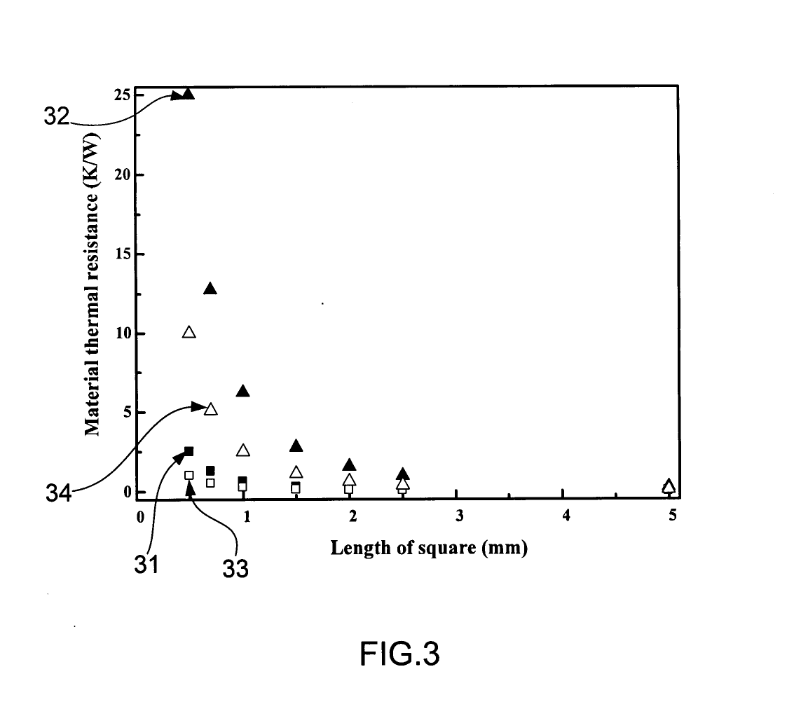

Please refer to FIG. 2 and FIG. 3, which are views showing curves of some specific thermal resistances and curves of one-dimensional material thermal resistances. As shown in the figures, a heat source and a submount are square and a ratio of a contact area between the heat source and the sub mount is 4/9. In FIG. 2, there are a first curve 21 for a spreading thermal resistance of 0.01 Biot number; a second curve 22 for an internal thermal resistance of 0.01 Biot number; a third curve 23 for a spreading thermal resistance of 10000 Biot number; a fourth curve 24 for an internal thermal resistance of 10000 Biot number; and a fifth curve 25 for a one-dimensional material thermal resistance. As shown in the figure, the one-dimensional material thermal resistance of the submount has a coupling effect to the spreading thermal resistance of the submount. In FIG. 3, there are a first material thermal resistance curve 31 for a submount having a thickness of 0.1 millimeter (mm) and a thermal conductivity of 160 W/mK; a second material thermal resistance curve 32 for a submount having a thickness of 1 mm and a thermal conductivity of 160 W/m K; a third material thermal resistance curve 33 for a submount having a thickness of 0.1 mm and a thermal conductivity of 400 W/m K; and a fourth material thermal resistance curve 34 for a submount having a thickness of 1 mm and a thermal conductivity of 400 W/mK. As shown in the figure, when the side length of the electrical component is becoming smaller, the thermal resistance of the submount is dramatically increased. In the present invention, a ratio of height to side length is set between 0.05 and 0.45. And, according to the above two figures, the present invention effectively diminishes a spreading thermal resistance and obtains a low internal thermal resistance.

To sum up the present invention is a structure of a heat dissipated sub mount, which effectively diminishes a spreading thermal resistance of a submount and obtains a characteristic of high heat density dissipating.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A structure of a heat dissipated submount, comprising:
a submount, said submount having at least one heat source at a side; and
a cooling device, said cooling device being deposed at a side of said submount not adjacent to said heat source.

2. The structure according to claim 1,
where in said submount has a thermal conductivity between 1 watt per meter per kelvin (W/mK) and 2000 W/mK.

3. The structure according to claim 1,
wherein said submount is made of a material selected from a group consisting of silicon carbide, aluminum nitride, aluminum, copper and diamond.

4. The structure according to claim 1,
where in said submount is selected from a group consisting of a heat pipe, a heat spreader or a micro heat pipe.

5. The structure according to claim 1,
wherein said submount has a square bottom;
wherein said square bottom has a side length smaller than 5 centimeter (cm); and
wherein a ratio of a height of said submount to said side length of said submount is between 0.05 and 0.45.

6. The structure according to claim 1,
wherein said submount has a circular bottom;
wherein said circular bottom has a diameter smaller than 5 cm; and
where in a ratio of a height of said submount to said diameter of said submount is between 0.05 and 0.45.

7. The structure according to claim 1
wherein said cooling device is selected from a group consisting of a plurality of heat dissipated fins, a water cooler and a thermoelectric cooler (TE-cooler).

8. The structure according to claim 1,
wherein said heat source is selected from a group consisting of an electric chip and a light-emitting diode (LED).

9. The structure according to claim 1,
where in said at least one heat source has an array arrangement.

10. The structure according to claim 1,
wherein said heat source has a bottom selected from a group consisting of a square bottom and a circular bottom.

11. A structure of a heat dissipated submount, comprising:
a submount, said submount having at least one heat source at a side, said submount having a square bottom, said square bottom having a side length smaller than 5 cm, said submount having a ratio of a height of said submount to said side length of said submount between 0.05 and 0.45; and
a cooling device, said cooling device being deposed at a side of said submount not adjacent to said heat source.

12. The structure according to claim 11,
wherein said submount has a thermal conductivity between 1 W/mK and 2000 W/mK.

13. The structure according to claim 11,
wherein said submount is made of a material selected from a group consisting of silicon carbide,
aluminum nitride, aluminum, copper and diamond.

14. The structure according to claim 11,
wherein said submount is selected from a group consisting of a heat pipe, a heat spreader or a micro heat pipe.

15. The structure according to claim 11,
wherein said submount has a circular bottom;
where in said square bottom has a diameter smaller than 5 cm; and
wherein a ratio of a height of said submount to said diameter of said submount is between 0.05 and 0.45.

16. The structure according to claim 11,
wherein said cooling device is selected from a group consisting of a plurality of heat dissipated fins, a water cooler and a TE-cooler.

17. The structure according to claim 11,
where in said heat source is selected from a group consisting of an electric chip and a LED.

18. The structure according to claim 11,
where in said at least one heat source has an array arrangement.

19. The structure according to claim 11,
wherein said heat source has a bottom selected from a group consisting of a square bottom and a circular bottom.
